(19) United States
(12) Patent Application Publication
(10) Pub. No.: US 2008/0315201 A1
(43) Pub. Date: Dec. 25, 2008

(54) Apparatus for Producing Electronic Device Such as Display Device, Method of Producing Electronic Device Such as Display Device, and Electronic Device Such as Display Device

(75) Inventors: Tadahiro Ohmi, Miyagi (JP); Akihiro Morimoto, Miyagi (JP); Takeyoshi Kato, Miyagi (JP)

Correspondence Address: FOLEY AND LARDNER LLP;SUITE 500, 3000 K STREET NW, WASHINGTON, DC, 20007, US

(73) Assignee: Tadahiro OHMI

(21) Appl. No.: 11/992,046

(22) PCT Filed: Sep. 16, 2005
(86) PCT No.: PCT/JP2005/017184

§ 371 Date: Apr. 25, 2008

(51) Int. Cl. H01L 29/04; C23C 16/513; H01L 21/263

(52) U.S. Cl. 257/59; 118/64; 438/795; 257/E21.333; 257/E29.004

(57) ABSTRACT

An object of the present invention is to reduce an adverse effect of an atmosphere in a heat treatment device used in production of an electronic device, imparted on characteristics of the produced electronic device. To attain the object, an inner surface of the heat treatment device is covered with an oxide passive-state film and bringing the surface roughness of the inner surface to 1 μm or less in terms of a central mean roughness Ra. According to this type of heat treatment device, in curing a heat curable resin, deterioration in the heat curable resin caused by decomposition or dissociation of the heat curable resin, can be reduced.

### TECHNICAL FIELD

The present invention relates to an apparatus for manufacturing an electronic device containing a display device such as a flat panel display and a printed wiring board, a method of manufacturing the same, and the manufactured electronic device containing a display device such as a flat panel display and a printed wiring board.

### BACKGROUND ART

Conventionally, any types of electronic devices are manufactured while containing a wiring layer which is formed together with an insulating layer on a substrate. As an example, a display device, in particular, a flat panel display device is described. A liquid crystal display device and an organic EL display device has a wiring structure for thin film transistors (hereinafter, also referred to as TFTs) arranged in matrix (active matrix structure).

An active matrix structure is formed of scanning lines for transmitting timing in writing a data signal, signal lines for supplying a pixel with a data signal according to an image to be displayed, and a thin film transistor as a switching device for supplying a data signal to a pixel according to a timing signal generated on the scanning lines. The substrate including the scanning lines, the signal lines, and the TFTs is also referred to as an active matrix substrate. The substrate is formed with layers of circuit patterns formed on a surface thereof by a process such as film formation in a reduced-pressure atmosphere or photolithography.

On the other hand, in order to improve performance of a display device, studies to make higher an effective pixel area ratio of the display device, which is referred to as an aperture ratio have been conducted. A first method is disclosed in Japanese Unexamined Patent Application Publication (JP-A) No. H09-080416 (Patent Document 1), Japanese Unexamined Patent Application Publication (JP-A) No. H09-090404 (Patent Document 2), and the like, and it is attempted that the aperture ratio is made higher by forming an interlayer insulating film for covering TFTs which normally have irregularities and further forming thereon a transparent electrode by vapor deposition or sputtering to have a multilayer structure of signal lines and the transparent electrode. It is said that, in this structure, the light transmittance of the interlayer insulating film is required to be 90% or more. As a second method, inventors of the present invention proposed that, in WO2005/057530A1 (Patent Document 3), a planarization layer be formed so as to surround gate wiring in order to absorb irregularities due to the gate wiring. Further, by making signal lines a thick film and making a wiring width narrow, the higher aperture ratio is materialized. In both of the first and second methods, a transparent heat curable resin is used for the interlayer insulating film and the planarization layer.

Under present circumstances, no environmental control is performed on an atmosphere when the heating is carried out for the curing. Generally, it is often the case that the heating is carried out in an environment of, for example, an atmosphere or nitrogen containing impurities on the order of percent. Therefore, depending on the conditions, the heat curable resin is decomposed or dissociated, the light transmittance is lowered, and as a result, the display performance is deteriorated, for example, the brightness of the display device is lowered. A reason for the deterioration of the light transmittance is, for example, heat treatment at or above a temperature where the heat curable resin is thermally decomposed, or promotion of deterioration of the heat curable resin due to residual oxygen or residual moisture in the atmosphere of heat treatment.

On the other hand, when a planarization layer is formed so as to surround gate wiring, as a structure of an active matrix substrate, it is necessary to form a semiconductor layer for TFTs immediately above the planarization layer by a plasma processing apparatus. Generally, in plasma film formation, the temperature of a surface of a substrate reaches 300-350° C. Further, it has been recognized that, in a process of forming a semiconductor layer, intrusion of moisture and a carbon component from an atmosphere of the process has a profound effect on semiconductor characteristics. Therefore, in order to suppress the amount of gas generated from the planarization layer, heat treatment at a temperature which is equal to or higher than the temperature at which the semiconductor layer is formed, for example, at 300° C. or higher is necessary. However, in a present process of heating a heat curable resin for forming a planarization layer, control of the amount of residual oxygen and of the amount of moisture in an atmosphere is not enough, and thus, there is a problem that the heat curable resin is deteriorated to lower the light transmittance.

The above-mentioned problem is not limited to an active matrix substrate, and in the process toward finer design rules, a printed board and an electronic device in general have the same problem.

Patent Document 1: JP H09-080416 A

Patent Document 2: JP H09-090404 A

Patent Document 3: WO2005/057530 A1

### DISCLOSURE OF THE INVENTION

### Problem to be Solved by the Invention

An object of the present invention is to provide an apparatus for manufacturing an electronic device that enables control of a heating atmosphere which is effective in making higher the performance and reliability of the electronic device.

Another object of the present invention is to provide an electronic device such as a display device of high performance and high reliability manufactured by the method.

### Means to Solve the Problem

In order to attain the above objects, the inventors of the present invention have made an intensive study, and have found that, in manufacturing an electronic device, roughness and a material of an inner surface of manufacturing equipment, in particular, a heating apparatus have a profound effect on a content of impurities such as oxygen and moisture of a heating atmosphere, and that control of the amount of residual oxygen, the amount of residual moisture, and the amount of a reducing gas in the heating atmosphere is effective in improving transparency of a heat curable resin to complete the present invention.

Electronic device manufacturing equipment characterized in that surface roughness represented by center average roughness Ra of an inner surface of a heat treatment apparatus (20) for manufacturing the electronic device is 1 μm or less.

Further, according to the present invention, a manufacturing equipment of an electronic device is provided which is characterized in that the oxide passive-state film is formed by heat treating on the inner surface with an oxidizing gas brought into contact with the inner surface.

It is to be noted that the oxide passive-state film of the manufacturing equipment is preferably at least one of chromium oxide, aluminum oxide, and titanium oxide.

Further, according to the present invention, it is preferable that the atmosphere of the heat treatment is replaced by an inert gas and the concentration of the residual oxygen in the atmosphere is controlled to be 10 ppm or less. Further, it is preferable that the residual moisture is also controlled to be 10 ppm or less. Still further, it is preferable that 0.1-100 volume % of a reducing gas such as hydrogen is added to the inert gas.

A method of manufacturing an electronic device according to any one of claims 6 to 10, characterized in that the heat curable resin (44) comprises one or a plurality of resins selected from a group consisting of an acrylic resin, a silicone resin, a fluorine resin, a polyimide resin, a polyolefin resin, an alicyclic olefin resin, an epoxy resin, and a silica resin.

Further, the present invention provides an electronic device in general including a high performance display device such as a flat panel display device, a printed board, a personal computer, and a cellular phone terminal characterized by being manufactured by the above-mentioned manufacturing equipment and manufacturing method.

### EFFECT OF THE INVENTION

According to the present invention, by controlling the surface roughness of the inner surface of a heat treatment apparatus used in manufacturing an electronic device, adverse effects of decomposition, dissociation, or the like of a heat curable resin used in the heat treatment apparatus are alleviated, and a film with high light transmittance can be formed. Therefore, the present invention is applied with effect to manufacture of an electronic device including an active matrix substrate which requires a film with high light transmittance.

### BRIEF DESCRIPTION OF THE DRAWING

FIG. 1 is a view for explaining an evaluating apparatus for evaluating piping having an oxide passive-state film according to the present invention.

FIG. 2 is a graph for explaining the result of evaluation by the evaluating apparatus illustrated in FIG. 1.

FIG. 3 is a view for explaining a system for manufacturing an electronic device using a baking apparatus after a treatment according to the present invention.

FIG. 4 is a view for explaining a section of an active matrix substrate according to the present invention.

FIGS. 5(a) to 5(i) are views for explaining manufacturing steps of the active matrix substrate illustrated in FIG. 4 in order of sequence.

### BEST MODE FOR EMBODYING THE INVENTION

In embodiments of the present invention, as a material of an inner surface of a heat treatment apparatus for manufacturing an electronic device such as a display device, stainless steel and an aluminum alloy are applied. In particular, as the stainless steel, an austenitic stainless steel, a ferritic stainless steel, an austenitic-ferritic stainless steel, and a martensitic stainless steel can be used, and for example, austenitic stainless steels SU304, SUS304L, SU316, SUS316L, SUS317, SUS317L, and the like are suitably used. As surface polishing of the stainless steel, pickling, mechanical polishing, belt polishing, barrel polishing, buffing, fluidized grain polishing, lapping, burnishing, chemical polishing, electrolytic composite polishing, electrolytic polishing, or the like is possible. Of course, a plurality of these polishing methods may be used for one material in combination. However, buffing, fluidized grain polishing, lapping, burnishing, chemical polishing, electrolytic composite polishing, and electrolytic polishing in which the surface roughness of an inner surface of a heat treatment apparatus for manufacturing an electronic device such as a display device represented by center average roughness Ra is 1 μm or less are effective. The surface roughness represented by the center average roughness Ra is preferably 1 μm or less, more preferably 0.5 μm or less, and most preferably 0.1 μm or less. When the surface roughness represented by the center average roughness Ra is 1 μm or more, there is fear in that impurity gases and the like such as oxygen and moisture which are adsorbed on the inner wall of a container may be mixed in the atmosphere in a heating apparatus.

On the other hand, it is preferable that an oxide passive-state film is formed on the inner surface of the heat treatment apparatus for manufacturing an electronic device such as a display device according to the present invention by carrying out heat treatment in an oxidizing atmospheric gas described in Japanese Unexamined Patent Application Publication (JP-A) No. H7-233476 and Japanese Unexamined Patent Publication (JP-A) No. H1-302824.

As an embodiment, conditions for forming aluminum oxide are characterized in that an aluminum oxide passive-state film is formed with an oxidizing gas containing oxygen or moisture being in contact with stainless steel containing aluminum. The concentration of oxygen is 500 ppb-100 ppm and preferably 1 ppm-50 ppm. The concentration of moisture is 200 ppb-50 ppm and preferably 500 ppb-10 ppm. Further, the oxidizing gas may be oxidizing mixed gas containing hydrogen. The oxidizing temperature is 700° C.-1200° C. and preferably 800° C.-1100° C. The oxidizing time is 30 minutes to 3 hours.

The formation of the oxide passive-state film makes it possible to improve the corrosion resistance and to lower the amount of surface adsorbed moisture. Further, because, even stainless steel after surface cleaning such as electrolytic polishing can not adequately control moisture released from an inner surface of piping, it is preferable to form a passive film at portions in contact with a high purity inert gas or reducing gas for forming a heating atmosphere. The oxide passive-state film may be, for example, chromium oxide, aluminum oxide, or titanium oxide, but in view of the corrosion resistance of the material and in view of lowering the amount of adsorbed moisture on the inner surface, aluminum oxide is particularly desirable.

Further, with regard to the heating atmosphere of the heat curable resin used for an electronic device such as an active matrix display device which is applied to embodiments of the present invention, it is desirable to control the concentration of residual oxygen when the inside of the heat treatment apparatus is replaced by an inert gas to be 10 ppm or less. The kind of the inert gas is not particularly limited, and may be, for example, a noble gas such as helium, neon, argon, krypton, xenon, or radon, or nitrogen. In particular, in view of the availability of a high purity gas with impurities such as moisture being 1 ppb or less, argon or nitrogen is particularly desirable. The concentration of residual oxygen in the atmosphere in the heat treatment apparatus is 10 ppm or less, preferably 1 ppm or less, and more preferably 100 ppb or less. When the concentration of residual oxygen in the atmosphere is 10 ppm or more, deterioration of the heat curable resin by oxidation starts when the temperature in the heat treatment apparatus is 200° C. or more, and its transparency is deteriorated.

Adding a reducing gas to the inert gas atmosphere in the heat treatment apparatus has the effect of suppressing lowering of the light transmittance of the heat curable resin due to deterioration. The amount of the added reducing gas is, in relation to the inert gas, 0.1-100 volume %, preferably 1-50 volume %, and particularly preferably 10-30 volume %. When the amount of the added reducing gas is 0.1% or less, no effect of suppressing deterioration of the heat curable resin is obtained.

The kind of the reducing gas used in the present invention is not particularly limited as long as it has the effect of suppressing oxidation reaction of the resin, but in view of the effect of reduction and the availability of a high purity gas, hydrogen is preferable.

The wiring structure of an electronic device applied to the present invention is not particularly limited, but a structure in which a wiring layer is formed together with a planarization layer on an insulating substrate is preferred. For example, in a case of an active matrix substrate, it is preferred to employ a structure in which a scanning line, a signal line, and a thin film transistor provided in the vicinity of intersections of the scanning line and the signal line, with gate electrodes thereof being connected to the scanning line and source electrode or drain electrode thereof being connected to the signal line, a planarization layer existing between the thin film transistors and a transparent electrode, and the planarization layer being formed of a heat curable resin, or a structure in which the surfaces of the signal line, source electrode, and the drain electrode are substantially flush with the planarization layer surrounding them, and the planarization layer is formed of the heat curable resin. In particular, it is more preferred to employ the structure in which the surfaces of the signal line, source electrode, and drain electrode are substantially flush with the planarization layer surrounding them suppresses, compared with a typical structure, because deterioration of the light transmittance owing to an increase in the planarization layer.

The planarization layer used in the present invention is characterized by being formed of a resin, and is preferably formed of a photosensitive resin composition. Further, the planarization layer may contain an inorganic substance. More preferably, the planarization layer is formed using a resin composition containing an alkali-soluble alicyclic olefin resin and a radiation-sensitive component. The photosensitive resin composition may contain a resin selected from a group consisting of an acrylic resin, a silicone resin, a fluorine resin, a polyimide resin, a polyolefin resin, an alicyclic olefin resin, and an epoxy resin.

### EXAMPLES

Examples of the present invention are described in the following. It is to be noted that, of course, the present invention is not limited to the following examples. Further, analytical values in the following examples and comparative examples are determined by rounding-off.

Further, conditions for analysis in the following examples and comparative examples are as follows.

(Analysis Condition 1) X-ray photoelectron spectroscopy (hereinafter abbreviated as “XPS analysis”)

Apparatus: ESCA-1000 manufactured by SHIMADZU CORPORATION

(Analysis Condition 2) Atmospheric pressure ionization mass spectrometry (hereinafter, abbreviated as “API-MS analysis”)

Apparatus: FTS-50A manufactured by Bio-Rad Laboratories, Inc.

(Analysis Condition 3) Total light transmittance (Ultraviolet spectrophotometric analysis)

Apparatus: UV-2550 manufactured by SHIMADZU CORPORATION

The total light transmittance was defined as an average of light transmittances with regard to respective wavelengths between 400 nm and 800 nm.

(Analysis Condition 4) Residual film ratio (Irregularity measurement)

Apparatus: P-10 manufactured by KLA-Tencor Corporation The residual film ratio was defined as a value derived from the following equation:

residual film ratio=(film thickness after heat treatment/film thickness before heat treatment)×100.

### Example 1

In the present example, an inner surface of ferritic stainless steel piping containing 29.1 weight % of Cr was treated by electrolytic polishing and was used. The outside diameter of the piping was ¼ inch, the length of the piping was 2 m, and the surface roughness was about 0.5 μm. After the electrolytic polishing was carried out, the above-mentioned stainless steel was charged into a furnace. With an Ar gas which has the concentration of impurities of several ppb or less flowing through the furnace, the temperature was raised from room temperature to 550° C. spending one hour. Baking was carried out at that temperature for an hour to remove adhered moisture from the surface. After the above-mentioned baking was completed, the gas was switched to a treatment gas with the concentration of hydrogen being 10% and the concentration of moisture being 100 ppm, and heat treatment for three hours was carried out. A part of the piping was cut off, and it was confirmed by XPS analysis that 100% Cr₂O₃ was formed at a thickness of about 15 nm in a thickness direction on the inner surface of the piping.

### Example 2

In the present example, an inner surface of austenitic stainless steel piping containing 4.0 weight % of Al was treated by electrolytic polishing and was used. The size of the piping was similar to that in Example 1. After the electrolytic polishing was carried out, the above-mentioned stainless steel was charged into a furnace. With an Ar gas having the concentration of impurities of several ppb or less flowing through the furnace, the temperature was raised from room temperature to 400° C. for one hour. Baking was carried out at that temperature for an hour to remove adhered moisture from the surface. After the above-mentioned baking was completed, the gas was switched to an oxidizing atmosphere with the concentration of moisture being 5 ppm and further, with 10% hydrogen being added to the moisture mixed gas, and oxidation treatment was carried out at 900° C. for an hour. A part of the piping was cut off, and it was confirmed by XPS analysis that 100% Al₂O₃ was formed at a thickness of about 200 nm in a thickness direction on the inner surface of the piping.

[Evaluation of Dry-Down Characteristics of Piping after Various Kinds of Surface Treatments]

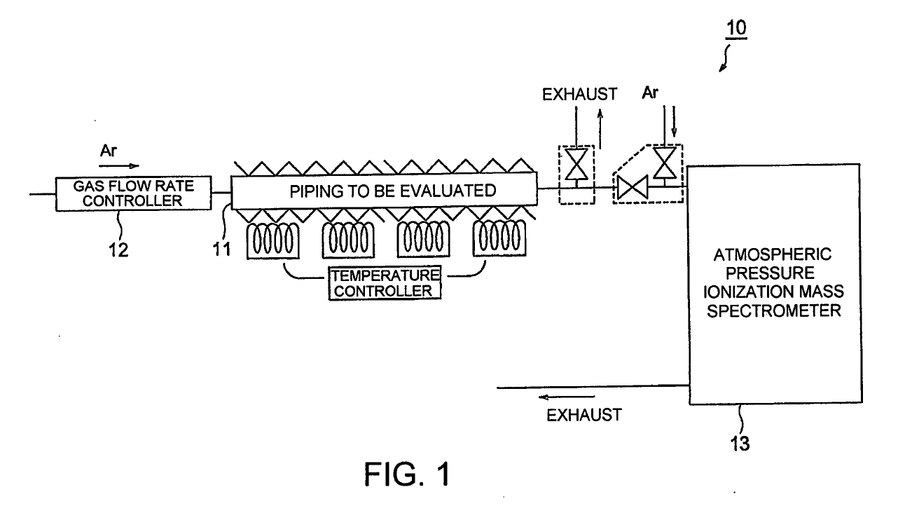

The stainless steel piping treated in Examples 1 and 2, SUS316-EP piping of the same size with its inner surface being treated by electrolytic polishing, and SUS316-BA piping after being annealed were used to evaluate dry-down characteristics of piping 11 by an evaluating apparatus 10 illustrated in FIG. 1. The piping 11 was heated to 500° C. in an argon gas atmosphere with the amount of moisture being 0.1 ppb or less to completely remove moisture adsorbed on the inner surface. After that, the piping was exposed to clean room air for 24 hours at a temperature of 23° C. with a relative humidity of 45%.

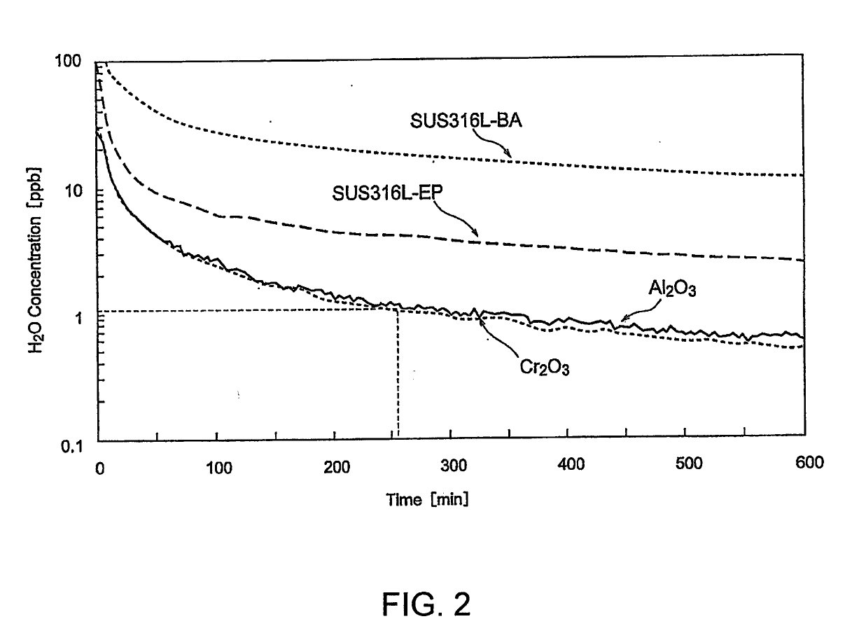

After that, an Ar gas was made to flow through the tube 11 having a diameter of ¼ inch and a length of 2 m after the various kinds of surface treatments from a gas flow controller 12 at a flow rate of 1.2 liters/min at room temperature for ten hours, and the amount of moisture in Ar during that time was measured by an atmospheric pressure ionization mass spectrometer (API-MS) 13. The result is illustrated in FIG. 2. It is to be noted that, because the amount of generated moisture is enormous in the first three minutes, the data begins at three minutes after the Ar gas starts to flow. While moisture of 10 ppb or more generates from the surface of annealed SUS316-BA even after Ar gas of 720 liters had flown for 10 hours, in the stainless steel piping treated in Examples 1 and 2 and the SUS316-EP piping treated by electrolytic polishing, the value was decreased as low as 3 ppb or less. In particular, in the stainless steel piping treated in Examples 1 and 2, the amount of generated moisture can be suppressed to be 1 ppb or less when the Ar gas of 280 liters flew for 4 hours.

### Example 3

### Spectrophotometric Analysis of Planarization Layer

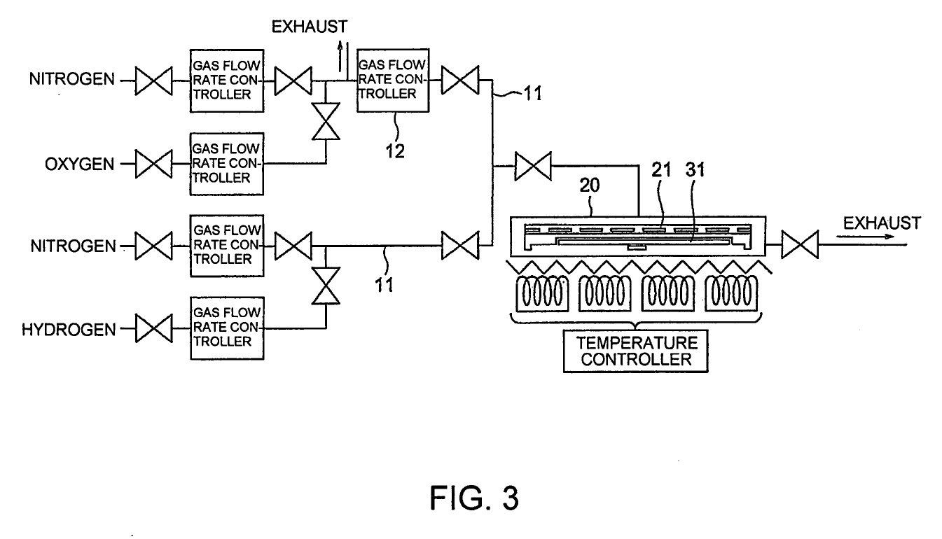

An alkali-free glass substrate 31 sized to be 20 mm×30 mm was, after being cleaned, dehydrated and heated in high purity nitrogen. After that, by treatment with hexamethylenedisilazane (HMDS) vapor, an adhesion layer was formed. After the adhering layer was formed, a photosensitive acrylic resin (positive type) which is a heat curable resin manufactured by JSR Corporation was applied by spin coating to form a resin film at a thickness of about 1 μm. The whole surface of the alkali-free glass substrate 31 with the resin film formed thereon was exposed to light at 500 mJ (g, h, and i beams are mixed) with a mask aligner (PLA501 manufactured by CANON). After the exposure, a baking apparatus 20 illustrated in FIG. 3 and having a SUS316L-EP inner surface 21 treated by electrolytic polishing was used, and, in an atmosphere where the concentration of oxygen was controlled to be 10 ppm with high purity nitrogen and oxygen in the apparatus, heating was carried out at 300° C. for 60 minutes to cure the resin film. With regard to the glass substrate 31 after the heat treatment, light transmittance was measured by a spectrophotometer and film thickness was measured by a probe type film thickness gauge. The result is shown in Table 1.

TABLE 1

| | kind of | | | | amount |
|---|---|---|---|---|---|
| | heat | | | light | of |
| | curable | | | trans- | reduced |
| | resin | oxygen | hydrogen | mittance | film |
| Example 3 | acrylic | 10 ppm | — | 99.2% | 93.5% |
| | resin | | | | |
| Example 4 | acrylic | — | 2% | 99.3% | 94.0% |
| | resin | | | | |
| Example 5 | alicyclic | 10 ppm | — | 99.5% | 98.1% |
| | olefin resin | | | | |
| Example 6 | alicyclic | — | 2% | 99.7% | 98.5% |
| | olefin resin | | | | |
| Example 7 | alicyclic | — | 20% | 99.8% | 98.5% |
| | olefin resin | | | | |
| Example 8 | silicone | 10 ppm | — | 99.0% | 98.8% |
| | resin | | | | |
| Example 9 | silicone | — | 2% | 99.1% | 98.9% |
| | resin | | | | |
| Example 10 | silicone | 10 ppm | 2% | 99.1% | 98.8% |
| | resin | | | | |
| Comparative | acrylic | 100 ppm | — | 98.7% | 93.1% |
| Example 1 | resin | | | | |
| Comparative | acrylic | 1000 ppm | — | 98.4% | 92.2% |
| Example 2 | resin | | | | |
| Comparative | alicyclic | 100 ppm | — | 99.3% | 98.3% |
| Example 3 | olefin resin | | | | |
| Comparative | silicone | 1% | — | 98.3% | 97.8% |
| Example 4 | resin | | | | |

### Comparative Example 1

Conditions were similar to those in Example 3 except that the concentration of oxygen in the baking apparatus 20 was controlled to be 100 ppm. The result is shown in Table 1.

### Comparative Example 2

Conditions were similar to those in Example 3 except that the concentration of oxygen in the baking apparatus 20 was controlled to be 1000 ppm. The result is shown in Table 1.

### Example 4

Conditions were similar to those in Example 3 except that 2% of hydrogen was added instead of oxygen. The result is shown in Table 1.

### Examples 5 and 6 and Comparative Example 3

Conditions were similar to those in Examples 3 and 4 and Comparative Example 1 except that a photosensitive alicyclic olefin resin (positive type) manufactured by ZEON Corporation was used as the heat curable resin. The result is shown in Table 1.

### Example 7

Conditions were similar to those in Example 6 except that hydrogen having the concentration of 20% was added. The result is shown in Table 1.

### Examples 8 and 9

Conditions were similar to those in Examples 5 and 6 except that a photosensitive silicon resin (negative type) manufactured by JSR Corporation was used as the heat curable resin. The result is shown in Table 1.

### Example 10

Conditions were similar to those in Example 8 except that the concentration of oxygen in the baking apparatus 20 was 10 ppm and 2% of hydrogen was added. The result is shown in Table 1.

### Comparative Example 4

Conditions were similar to those in Example 8 except that the concentration of oxygen in the baking apparatus 20 was controlled to be 1%. The result is shown in Table 1.

### Example 11

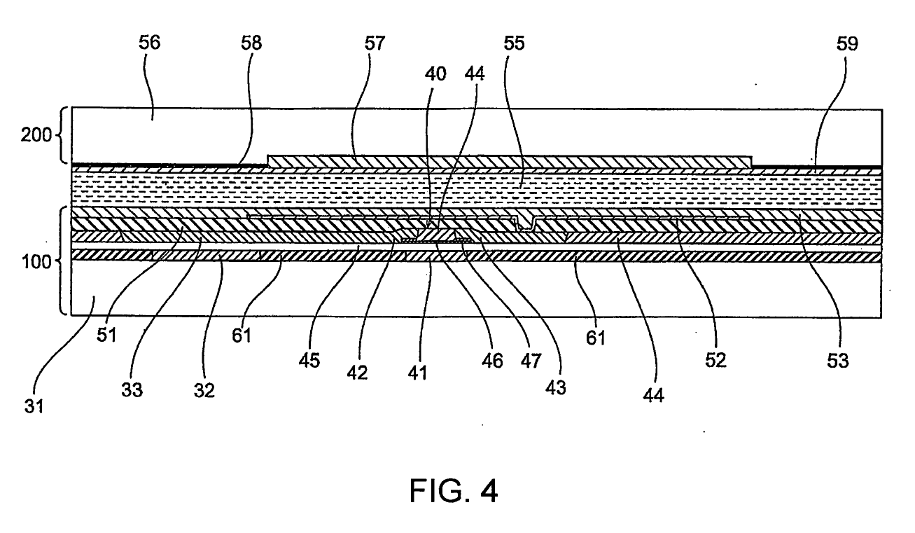

An active matrix liquid crystal display device in Example 11 according to the present invention is described with reference to FIG. 4. FIG. 4 is a sectional view illustrating a structure of the active matrix liquid crystal display device of Example 11 according to the present invention. The illustrated liquid crystal display device has a scanning line 32 and a signal line 33 formed on a glass substrate 31, and a thin film transistor 40 provided in the vicinity of an intersection of the scanning line 32 and the signal line 33. In the thin film transistor 40, a gate electrode 41 is connected to the scanning line 32 and a source electrode 42 or a drain electrode 43 thereof is connected to the signal line 33. A planarization layer 44 is formed so as to surround the signal line 33, the source electrode 42, and the drain electrode 43. The signal line 33, the source electrode 42, the drain electrode 43, and the planarization layer 44 form substantially the same plane.

A pixel electrode 52 is arranged above the plane via an interlayer insulating film 51. An oriented film 53 is formed on the pixel electrode 52 and the interlayer insulating film 51. In this way, an active matrix substrate 100 is formed. A filter substrate 200 is arranged so as to be opposed to the active matrix substrate 100. Liquid crystal 55 is sandwiched between the active matrix substrate 100 and the filter substrate 200. In this way, the active matrix liquid crystal display device is formed. It is to be noted that the filter substrate 200 is formed of an opposing glass substrate 56, a color filter 57, a black matrix 58, and an oriented film 59.

The scanning line 32 and the gate electrode wiring 41 of Example 11 are buried wiring using an inkjet method.

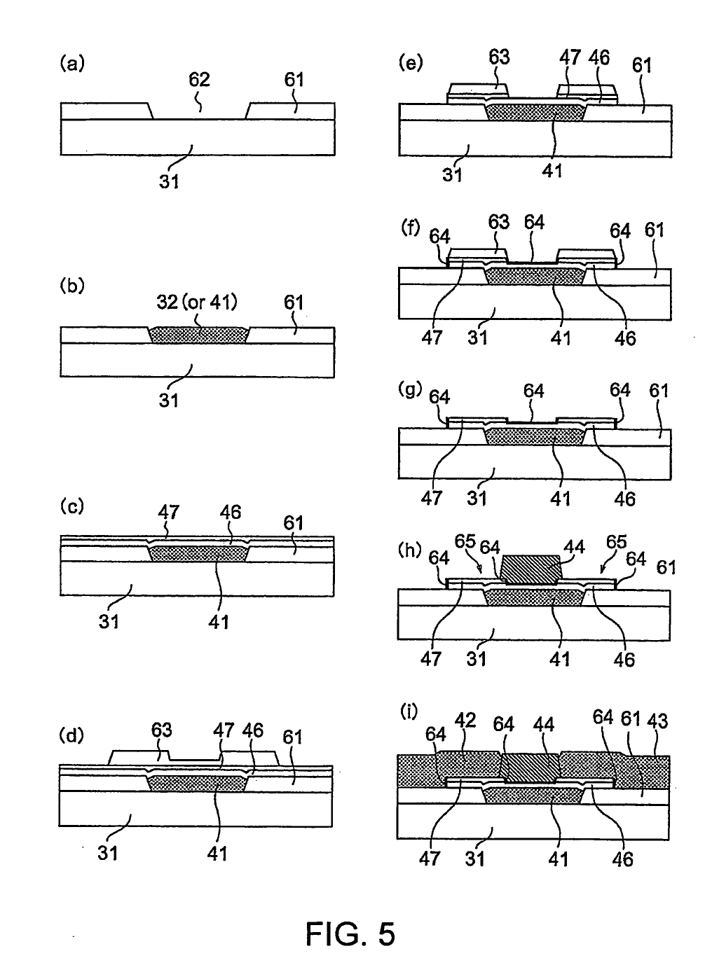

Manufacturing steps of the active matrix substrate 100 illustrated in FIG. 4 are described with reference to FIG. 5.

First, a method of forming a gate wiring portion is described with reference to FIGS. 5(a) to (d).

First of all, with reference to FIG. 5(a), a transparent resin film (heat curable resin) 61 which is a photosensitive alicyclic olefin resin is formed by spin coating or the like at a thickness of 1 μm on a surface of the glass substrate 31. The photosensitive resin film 61 has a function as a photoresist film. Next, by selectively exposing, developing, removing, and heating to cure the photosensitive transparent resin film 61 using active radiation, a groove 62 is formed in the photosensitive transparent resin film 61 as illustrated in FIG. 5(a).

With regard to the conditions for the heating and curing, in order to enhance the light transmittance of the photosensitive transparent resin 61, a heating apparatus with an inner surface thereof being SUS316 treated by electrolytic polishing was used, and further, the concentration of residual oxygen was controlled to be 10 ppm, and baking was carried out at 300° C. for 60 minutes. When the wiring width is narrow, in order to make higher the printing accuracy, the surface of the transparent resin layer 61 may be treated so as to be water-repellent. More specifically, for example, fluorine treatment of the surface using plasma of a fluorine gas such as NF₃ may be carried out, or, a resin precursor may be impregnated with a fluorine-based silylation reagent before the resin is heated to be cured.

Then, the groove portion 62 is filled with wiring precursor by a print process such as inkjet printing or plating. In view of efficient use of ink, the method of forming the wiring is preferably the inkjet method, but screen printing or the like may also be used. In this example, as the wiring precursor, silver paste ink similar to that disclosed in Japanese Unexamined Patent Application Publication (JP-A) No. 2002-324966 was used to form the wiring. After the filling with the wiring precursor, baking was carried out at a temperature of 250° C. for 30 minutes to form the scanning line 32 or the gate electrode wiring 41 (FIG. 5(b)).

Then, by plasma CVD using microwave-excited plasma, a silicon nitride film (an SiNx film) was formed as a gate insulating film 45 (see FIG. 4) using SiH₄ gas, H₂ gas, N₂ gas, and Ar gas. Although an SiNx film can be formed using ordinary RF-excited plasma, by using microwave-excited plasma, an SiNx film can be formed at a lower temperature. The film-forming temperature was 300° C. and the film thickness was 0.2 μm (not shown in FIG. 5(b)).

Then, by plasma CVD using microwave-excited plasma, an amorphous silicon layer as a first semiconductor layer 46 and an n+ type amorphous silicon layer as a second semiconductor layer 47 were formed. The amorphous silicon layer 46 used SiH₄ gas while the n+ type amorphous silicon layer 47 used SiH₄ gas, PH₃ gas, and Ar gas, and the film formation was carried out at 300° C. (FIG. 5(c)).

Then, photoresist was applied to the whole surface by spin coating, and drying was carried out at 100° C. for one minute on a hot plate to remove a solvent. Then, a g-line stepper was used to carry out exposure with an energy dose of 36 mJ/cm². In the exposure, a mask was formed so as to leave a device region, and, with regard to a portion corresponding to a channel region in the device region, a slit mask was used to adjust the exposure. As a result of puddle development for 70 seconds using a 2.38% TMAH solution, a photoresist film 63 in a shape illustrated in FIG. 5(d) was obtained.

Then, a plasma etching apparatus was used to etch the n+ type amorphous silicon layer 47 and the amorphous silicon layer 46. Because, here, the photoresist film 63 is etched to some extent and the film thickness decreases, the resist film portion of the thin channel region portion of the photoresist film 63 is etched and removed, and the n+amorphous silicon layer 47 is also etched. The n+ type amorphous silicon layer 47 and the amorphous silicon layer 46 other than the device region portion were etched and removed. The etching was completed when the n+ type amorphous silicon layer 47 on the channel region was etched and removed, and then, a shape illustrated in FIG. 5(e) was obtained. In this state, as is apparent from FIG. 5(e), the photoresist film 63 on the n+ type amorphous silicon layer 47 in the source electrode portion and the drain electrode portion is left.

Then, with this state maintained, microwave-excited plasma treatment was carried out using Ar gas, N₂ gas, and H₂ gas to directly form a nitride film 64 on the surface of the amorphous silicon layer 46 in the channel portion (FIG. 5(f)). Although the nitride film 64 can be formed using ordinary RF plasma, by using microwave-excited plasma, plasma with low electron temperature can be generated, and thus, the nitride film 64 can be formed without damage caused by plasma to the channel portion, which is preferable. Further, although it is also possible to form the nitride film 64 by CVD, the nitride film is formed also in a source electrode region and a drain electrode region and a step of removing them is necessary later, and thus, it is more preferable to directly form the nitride film 64.

Then, by carrying out oxygen plasma ashing and then removing with a resist stripper or the like the photoresist film 63 which remains on the source electrode region and the drain electrode region, a shape as illustrated in FIG. 5(g) is obtained.

Then, as a wiring formation assist layer 44 which is necessary when the signal line 33, the source electrode wiring 42, and the drain electrode wiring 43 are formed by a print process such as inkjet printing method or plating, a photosensitive transparent resin film precursor (heat curable resin) which is an alicyclic olefin resin is applied. By carrying out exposure, development, and heating for curing using a photomask for the signal line 33, the source electrode wiring 42, and the drain electrode wiring 43, the transparent resin layer 44 is formed, and, as illustrated in FIG. 5(h), a groove 65 to be a region for the signal line 33, the source electrode wiring 42, and the drain electrode wiring 43 is obtained.

With regard to the conditions for the heating and curing, in order to enhance the light transmittance of the photosensitive transparent resin 44, a heating apparatus with an inner surface thereof being SUS316 treated by electrolytic polishing was used, and further, the concentration of residual oxygen was controlled to be 10 ppm, and baking was carried out at 250° C. for 60 minutes. When the wiring width is narrow, in order to make higher the printing accuracy, the surface of the transparent resin layer 44 may be treated so as to be water-repellent. More specifically, for example, fluorine treatment of the surface using plasma of a fluorine gas such as NF₃ may be carried out, or, a resin precursor may be impregnated with a sililation reagent including fluorine before post bake of the resin.

Then, the groove portion 62 is filled with wiring precursor by a print method such as inkjet printing method or plating. In view of efficient use of ink, the method of forming the wiring is preferably the inkjet method, but screen printing or the like may also be used. In the present example, as the wiring precursor, silver paste ink similar to that disclosed in JP 2002-324966 A was used to form the wirings 42, 43. In this case, after the filling with the wiring precursor, baking was carried out at a temperature of 250° C. for 30 minutes to form the scanning line 32 or the gate electrode wirings 42, 43 (FIG. 5(i)).

In this way, formation of the TFT 40 was completed.

Then, by forming, exposing, and developing a photosensitive transparent resin which is an alicyclic olefin resin as the interlayer insulating film 51, a contact hole from the pixel electrode 52 to the TFT electrode (here, the drain electrode wiring 43) was formed. With regard to the curing of the photosensitive transparent resin 51, similarly to the steps described in the above, in order to enhance the light transmittance of the photosensitive transparent resin 51, a heating apparatus with an inner surface thereof being SUS316 treated by electrolytic polishing was used. Further, the concentration of residual oxygen was controlled to be 10 ppm, and baking was carried out at 250° C. for 60 minutes.

Then, an indium tin oxide (ITO) film was formed by sputtering on the whole surface of the substrate. The film was patterned to form a pixel electrode (transparent electrode) 52. Instead of ITO, a transparent conductive film material such as SnO₂ may be used. A polyimide film was formed on the surface as a liquid crystal oriented film 53. By sandwiching the liquid crystal 55 between the polyimide film 53 and the opposing filter substrate 200, an active matrix liquid crystal display device was obtained.

According to an active matrix liquid crystal display device of the present example, because the transparency of the planarization layer 44 is high, low power consumption, high brightness, and high quality display could be obtained.

### INDUSTRIAL APPLICABILITY

The present invention is applicable not only to manufacture of a display device such as an active matrix substrate but also to manufacture of various kinds of electronic devices including a printed wiring board.

1. An apparatus for manufacturing an electronic device, wherein a surface roughness represented by a center average roughness Ra of an inner surface of a heat treatment apparatus for manufacturing the electronic device is 1 μm or less.

2. An apparatus for manufacturing an electronic device, wherein a surface roughness represented by a center average roughness Ra of an inner surface of a heat treatment portion and a piping system for supplying a high purity inert gas to the treatment portion is 1 μm or less.

3. An apparatus for manufacturing an electronic device according to claim 1 or 2, wherein the inner surface has an oxide passive-state film comprising at least one of chromium oxide, aluminum oxide, titanium oxide, yttrium oxide, and magnesium oxide.

4. An apparatus for manufacturing an electronic device according to claim 1 or 2, wherein the oxide passive-state film is formed by heat treating on the inner surface with an oxidizing gas brought into contact with the inner surface.

5. An apparatus for manufacturing an electronic device according to claim 1 or 2, wherein the oxide passive-state film is formed on the inner surface by flame spraying.

6. A method of manufacturing an electronic device, comprising the step of curing a heat curable resin, wherein the curing step comprises heat treatment carried out in a heat treatment apparatus, a surface roughness represented by a center average roughness Ra of an inner surface of the heat treatment apparatus is 1 μm or less.

7. A method of manufacturing an electronic device according to claim 6, wherein the inner surface has an oxide passive-state film comprising at least one of chromium oxide, aluminum oxide, titanium oxide, yttrium oxide, and magnesium oxide.

8. A method of manufacturing an electronic device according to claim 6, wherein the heat treatment is carried out in an atmosphere including an inert gas and a concentration of residual oxygen in the atmosphere of the heat treatment is controlled to be 10 ppm or less.

9. A method of manufacturing an electronic device according to claim 8, wherein the inert gas included in the atmosphere of the heat treatment is supplied via piping system, when the surface roughness represented by the center average roughness Ra of an inner surface thereof is 1 μm or less.

10. A method of manufacturing an electronic device, comprising the step of curing a heat curable resin, wherein the curing step comprises heat treatment carried out in an atmosphere including an inert gas and a concentration of residual oxygen in the atmosphere of the heat treatment is controlled to be 10 ppm or less.

11. A method of manufacturing an electronic device according to claim 8, 9, or 10, wherein 0.1-100 volume % of a reducing gas is added to the inert gas atmosphere.

12. A method of manufacturing an electronic device according to claim 11, wherein the reducing gas comprises hydrogen.

13. A method of manufacturing an electronic device according to claim 8, 9, or 10, wherein a concentration of residual moisture in the atmosphere of the heat treatment is controlled to be 10 ppm or less.

14. A method of manufacturing an electronic device according to any one of claims 6 to 10, wherein the heat curable resin comprises one kind or a plurality of kinds of resins selected from the group consisting of: acrylic resins, silicone resins, fluorine resins, polyimide resins, polyolefin resins, alicyclic olefin resins, epoxy resins, and silica resins.

15. An electronic device comprising a heat curable resin layer, wherein the heat curable resin layer is manufactured by the method according to any one of claims 6 to 10.

16. An electronic device according to claim 15, wherein the electronic device comprises a substrate and the heat curable resin layer is arranged together with wiring layers on the substrate.

17. An electronic device having an active matrix substrate, the active matrix substrate comprising on an insulating substrate:
at least,
a scanning line;
a signal line; and
a thin film transistor provided in a vicinity of intersections of the scanning line and the signal line, a gate electrode of the thin film transistor is connected to the scanning line, one of a source electrode and a drain electrode of the thin film transistor is connected to the signal line; and
a planarization layer between the thin film transistor and a transparent electrode,
wherein the planarization layer is formed of a heat curable resin and the heat curable resin is cured by the method according to any one of claims 6 to 10.

18. An electronic device having an active matrix substrate (100), the active matrix substrate comprising on an insulating substrate:
at least,
a scanning line (32);
a signal line; and
a thin film transistor provided in a vicinity of intersections of the scanning line and the signal line, a gate electrode of the thin film transistor is connected to the scanning line, and one of a source electrode and a drain electrode of the thin film transistor is connected to the signal line,
surfaces of the signal line, the source electrode, and the drain electrode being substantially flush with a surrounding planarization layer,
wherein the planarization layer is formed of a heat curable resin and the heat curable resin is cured by the method according to any one of claims 6 to 10.

19. An electronic device according to claim 15, wherein the heat curable resin comprises one kind or more of resins selected from the group consisting of: acrylic resins; silicone resins; fluorine resins; polyimide resins; polyolefin resins; alicyclic olefin resins; epoxy resins; and silica resins.

20. An electronic device according to claim 17, wherein the planarization layer comprises a resin composition comprising an alkali-soluble alicyclic olefin resin and a radiation-sensitive component.

21. An electronic device according to claim 18, wherein the planarization layer comprises a resin composition comprising an alkali-soluble alicyclic olefin resin and a radiation-sensitive component.

22. An electronic device according to claim 15, wherein the electronic device is one of a flat panel display device, a printed board, a personal computer, and a cellular phone terminal.

23. An electronic device according to claim 15, wherein the electronic device is one of a liquid crystal display device and an organic EL display device.

24. An electronic device comprising a resin film having light transmittance of 99% or more between a plasma CVD film and a transparent substrate, wherein the resin film is manufactured by the method according to any one of claims 6 to 10.

25. An electronic device according to claim 24, wherein the heat curable resin comprises one kind or a plurality of kinds of resins selected from the group consisting of: acrylic resins; silicone resins; fluorine resins; polyimide resins; polyolefin resins; alicyclic olefin resins; epoxy resins; and silica resins.
